(19) United States
(12) Patent Application Publication
(10) Pub. No.: US 2023/0380107 A1
(43) Pub. Date: Nov. 23, 2023

(54) IMMERSION COOLING SYSTEM AND LEVEL CONTROL METHOD THEREOF

(71) Applicants: Inventec (Pudong) Technology Corporation, Shanghai (CN); INVENTEC CORPORATION, Taipei (TW)

(72) Inventors: Kai-Yang TUNG, Taipei (TW); Hung-Ju Chen, Taipei (TW)

(21) Appl. No.: 17/901,956

(22) Filed: Sep. 2, 2022

(30) Foreign Application Priority Data
May 23, 2022 (CN) 202210561539.9

(51) Int. Cl. H05K 7/20

(52) U.S. Cl. CPC H05K 7/20281; H05K 7/20763; H05K 7/20236

(57) ABSTRACT

An immersion cooling system and level control method thereof, comprising: provide a main tank with a first upper/lower level limit and a storage tank with a second upper/lower level limit, the connection site of the main tank is higher than that of the storage tank and the first upper level limit; measure the level of the two tanks; when the level of the main tank is lower than the first lower level limit and the level of the storage tank is higher than the second lower level limit, open a first valve and a pump so that the liquid is input into the main tank; and when the level of the main tank is higher than the first upper level limit and the level of the storage tank is not higher than the second upper level limit, open the second valve to allow liquid to enter the storage tank.

### CROSS-REFERENCE TO RELATED APPLICATIONS

This non-provisional application claims priority under 35 U.S.C. § 119(a) on Patent Application No(s). 202210561539.9 filed in China on May 23, 2022, the entire contents of which are hereby incorporated by reference.

### BACKGROUND

### 1. Technical Field

This disclosure relates to a method for controlling liquid level, particularly to a method for controlling liquid level of an immersion cooling system.

### 2. Related Art

Immersion cooling systems are usually categorized into two types: single-phase immersion cooling system and two-phase immersion cooling system, and the former one creates circulation primarily based on heat convection, while the latter one transfers heat through phase-change of the cooling liquid with a low boiling point. A two-phase cooling system has a tank filled with dielectric liquid, in which the electronic device to be cooled is soaked. In order to prevent the liquid level from being too high to overflow the tank, generally, the electronic device to be cooled is placed into the tank first, then the dielectric liquid is poured in to a predetermined level.

In current design, when the liquid level in the tank drops lower than the predetermined level due to the occurring of evaporation or overflow, the system will activate safety mechanism to turn off the server in the tank to prevent part of the electronic devices being overheated or even damaged since part of the electronic devices can't be immersed under the liquid level which is too low. At the same time, the system will deliver a warning signal to request the operator to replenish the liquid, and after the liquid level returns to the predetermined range, the server is allowed to restart, which naturally increases the shutdown duration of the system.

In addition, during the process of taking out the server from the tank, if the volume of the tank is relatively small causing an electronic device proportionally occupies more space in the tank, or if a plurality of servers are taken out at once, the volume originally occupied by the electronic device of the dielectric liquid will dramatically decrease due to removal, which leads to the drop of the liquid level also leads to a possibility to trigger the safety mechanism to shut down the rest of the servers in the tank. To prevent the above situation from happening, a solution of pouring the dielectric liquid into the tank in advance may maintain the liquid level within the predetermined range. However, when the server is placed back to the tank, the extra dielectric liquid has to be removed to prevent the liquid in the tank from being excessive, which increases the possibility of overflow. Besides, in the two-phase system, excessively high liquid level may result in direct contact between the dielectric liquid and the condenser, which transforms the heat transfer phenomenon into a single-phase cooling without phase change, and therefore, may reduce the efficiency of the condenser. The complicated processing of pouring additional liquid into the tank before taking out the electronic device and removing excessive liquid after placing back the electronic device not only increases the burden on the operator but also easily causes accidental liquid leakage during the process, which further exacerbates the leakage of liquid.

### SUMMARY

Accordingly, this disclosure provides an immersion cooling system and level control method thereof.

According to one or more embodiment of this disclosure, an immersion cooling system comprises a main tank, a storage tank, a set of first level gauges, a set of second level gauges and a processing controlling unit, wherein the storage tank is connected to the main tank through the first pipeline and the second pipeline. The main tank has a first level lower limit and a first level upper limit, and is configured to accommodate an electronic device to be cooled. The storage tank has a second level lower limit and a second level upper limit. The first pipeline is provided with a first valve and a pump. The second pipeline is provided with a second valve, and a connection site between the main tank and the second pipeline is higher than a connection site between the storage tank and the second pipeline. The second level gauge is disposed in the storage tank, and configured to measure the liquid level of the storage tank. The processing controlling unit is connected to the first valve, the second valve, the pump, the set of first level gauges and the set of second level gauges, and is configured to perform: when it is determined that the level of the main tank is lower than the first level lower limit and the level of the storage tank is higher than the second level lower limit, opening the first valve and turning on the pump to input liquid into the main tank from the storage tank through the first pipeline; and when it is determined that the level of the main tank is higher than the first level upper limit and the level of the storage tank is not higher than the second level upper limit, opening the second valve to input liquid into the storage tank from the main tank through the second pipeline.

According to one or more embodiment of this disclosure, a method for controlling liquid level of an immersion cooling system comprises: providing a main tank and a storage tank, wherein the main tank has a first level lower limit and a first level upper limit, the storage tank has a second level lower limit and a second level upper limit, the main tank and the storage tank are connected to each other through a first pipeline and a second pipeline, the first pipeline is provided with a first valve and a pump, the second pipeline is provided with a second valve, and a connection site between the second pipeline and the main tank is higher than a connection site between the second pipeline and the storage tank and is lower than or equal to the first level upper limit; measuring a level of the main tank with a set of first level gauge; measuring a level of the storage tank with a set of second level gauge; and a processing controlling unit performing: when it is determined that the level of the main tank is lower than the first level lower limit and the level of the storage tank is higher than the second level lower limit, opening the first valve and turning on the pump to input liquid into the main tank from the storage tank through the first pipeline; and when it is determined that the level of the main tank is higher than the first level upper limit and the level of the storage tank is not higher than the second level upper limit, opening the second valve to input the liquid into the storage tank from the main tank through the second pipeline.

In view of the above description, an immersion cooling system and level control method thereof disclosed in the present invention provides a structure of the main tank in connection with the storage tank through pipeline, with the function of the level gauges, the pump and the processing controlling unit, to perform determination according to a requirement of the level of the main tank and the level condition of the storage tank. Therefore, liquid may be inputted into the storage tank from the main tank or liquid may be inputted into the main tank from the storage tank without encountering a situation that the level of the storage tank is too low to provide liquid into the main tank or that the level of the storage tank is too high to further accept liquid from the main tank. Accordingly, proper amount of cooling liquid inside the main tank may be ensured, so that the shutdown duration due to level variation in system may be reduced and the operation of cooling may be simplified. Furthermore, by the design of the connection site between the main tank and the second pipeline being higher than the connection site between the storage tank and the second pipeline, gravitational effect of height difference may be used to reduce energy loss required to perform reflow.

The above descriptions about the present disclosure and the explanation of implementation hereinafter is to demonstrate and to explain spirits and principles of the present invention, and provides further explanations to the claims of the present invention.

### BRIEF DESCRIPTION OF THE DRAWINGS

The present disclosure will become more fully understood from the detailed description given hereinbelow and the accompanying drawings which are given by way of illustration only and thus are not limitative of the present disclosure and wherein:

FIG. 1 is a schematic diagram illustrating an immersion cooling system according to an embodiment of the present invention;

FIG. 2 is a flowchart illustrating a method for controlling liquid level of an immersion cooling system according to an embodiment of the present invention;

FIG. 3 is a flowchart illustrating a method for controlling liquid level of an immersion cooling system according to another embodiment of the present invention;

FIG. 4 is a flowchart illustrating a method for controlling liquid level of an immersion cooling system according to still another embodiment of the present invention;

FIG. 5 is a flowchart illustrating a method for controlling liquid level of an immersion cooling system according to further another embodiment of the present invention; and

FIG. 6 is a structural schematic diagram illustrating an immersion cooling system according to another embodiment of the present invention.

### DETAILED DESCRIPTION

In the following detailed description, for purposes of explanation, numerous specific details are set forth in order to provide a thorough understanding of the disclosed embodiments. According to the description, claims and the drawings disclosed in the specification, one skilled in the art may easily understand the concepts and features of the present invention. The following embodiments further illustrate various aspects of the present invention, but are not meant to limit the scope of the present invention.

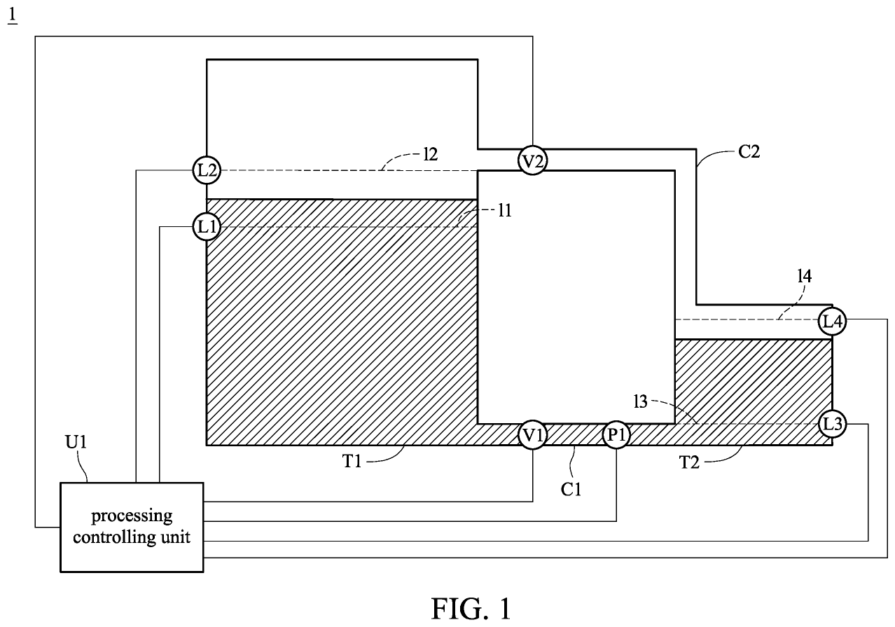

Please refer to FIG. 1, which is a schematic diagram illustrating an immersion cooling system according to an embodiment of the present invention. As illustrated in FIG. 1, the immersion cooling system 1 comprises a main tank T1, a storage tank T2, a set of first level gauges L1 and L2, a set of second level gauges L3 and L4, and a processing controlling unit U1, wherein the main tank T1 is connected to the storage tank T2 through a first pipeline C1 and a second pipeline C2. The main tank T1 has a first level lower limit l1 and a first level upper limit l2, and the storage tank T2 has a second level lower limit l3 and a second level upper limit l4. The set of first level gauges L1 and L2 are disposed in the main tank T1, which is configured to accommodate an electronic device to be cooled (e.g., server). The set of second level gauges L3 and L4 are disposed in the storage tank T2. The first pipeline C1 is provided with a first valve V1 and a pump P1. The second pipeline C2 is provided with a second valve V2, wherein a connection site between the second pipeline C2 and the main tank T1 is higher than a connection site between the second pipeline C2 and the storage tank T2 and is lower than or equal to the first level upper limit l2, and the first to fourth level gauges L1 to L4, the first and the second valves V1 and V2, and the pump P1 are signally connected to a processing controlling unit U1.

The processing controlling unit U1 may be, for example, a microcontroller unit, a programmable logic controller or a device capable of signal processing and controlling, or an integration of a number of the said devices. The processing controlling unit U1 may pre-store values of the first level lower limit l1, the first level upper limit l2, the second level lower limit l3 and the second level upper limit l4, may use the first and the second level gauges L1 and L2 to acquire the relationship between the level of the cooling liquid inside the main tank T1, the first level lower limit l1 and the first level upper limit l2, and may use the third and the fourth level gauges L3 and L4 to acquire the relationship between the level of the cooling liquid inside the storage tank T2, the second level lower limit l3 and the second level upper limit l4, thereby controlling the first and the second valves V1 and V2 and the pump P1 according to the above relationships, by which the specific method for controlling is described hereinafter. In addition to monitoring the level of the main tank T1, the processing controlling unit U1 may also additionally monitor the level of the storage tank T2 by which the specific method for controlling is described hereinafter.

Furthermore, the first level lower limit l1 of the main tank T1 may be set as the lowest level at which all the electronic devices to be cooled are still immersed in the liquid. The first level upper limit l2 of the main tank T1 is located higher than the first level lower limit l1, and may be set as being lower than a top opening of the main tank T1, thereby preventing liquid from overflow. The second level upper limit l4 of the storage tank T2 is located higher than the second level lower limit l3, and may be set as being lower than a top opening of the storage tank T2, thereby preventing liquid from overflow. One step further, the second level lower limit l3 of the storage tank T2 may be set as being higher than the connection site between the storage tank T2 and the first pipeline C1, thereby preventing the pump P1 from sucking in air. And in the two-phase system, the first level upper limit l2 of the main tank T1 may be set as being lower than a condenser (not illustrated in drawings) disposed in the main tank T1, thereby preventing contact between the condenser and liquid.

It should be noted that, even though FIG. 1 illustrates that the first level gauges L1 and L2 comprise two level gauges disposed at the first level upper limit l2 and the first level lower limit l1 respectively and that the second level gauges L3 and L4 comprise two level gauges disposed at the second level upper limit l4 and the second level lower limit l3 respectively as an example, the present invention is not intended to limit an amount or a position of the level gauge. For example, there may be two single optical level sensors for determining the level disposed in the main tank T1 and the storage tank T2 respectively, or the immersion cooling system 1 may be provided with a level gauge for determining the levels in the main tank T1 and the storage tank T2, and therefore, FIG. 1 is only an example illustration.

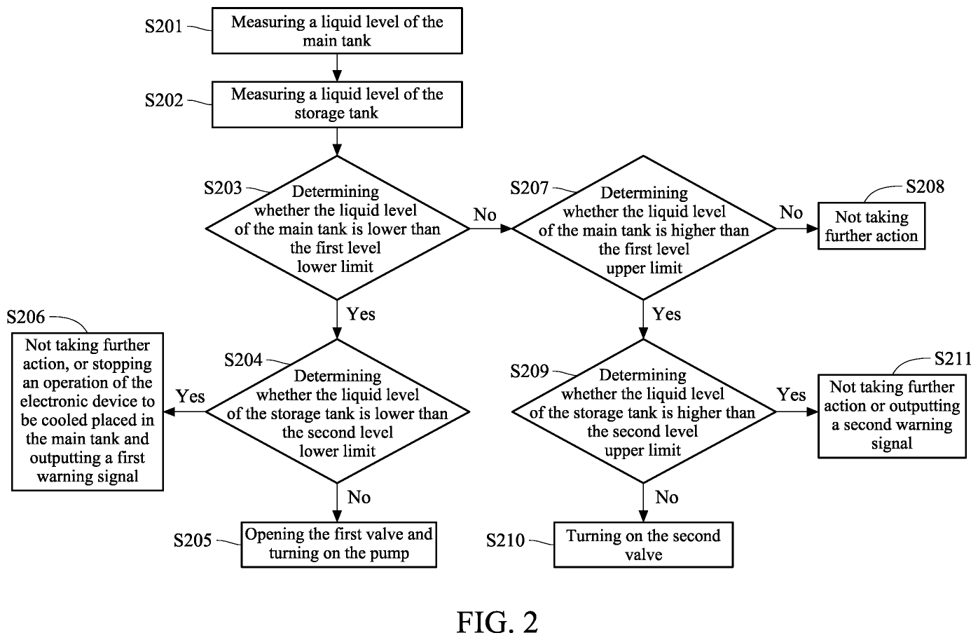

Please refer to FIG. 1 and FIG. 2, wherein FIG. 2 is a flowchart illustrating a method for controlling liquid level of an immersion cooling system according to an embodiment of the present invention. The method for controlling liquid level comprises providing the immersion cooling system 1 described in the embodiment above and performing steps S201 to S211 illustrated in FIG. 2 by the immersion cooling system 1. The following steps are illustrated by the operation of the immersion cooling system 1 illustrated in FIG. 1 as example. In step S201, the first level gauges L1 and L2 measure the liquid level of the main tank T1. It should be noted that, the level measurement of one or more embodiments of the present invention primarily focuses on the measurement of the height of the liquid, however, a measurement of volume is also an alternative scheme without deviating from the spirit of the present invention, and the detailed method for measurement can be understood by an ordinary people skilled in the art thus the description of the repetitive part omitted hereinafter. In addition, the level measured in step S201 may be expressed in many different ways. For example, “centimeter” may be used as unit for measurement record. However, the processing controlling unit U1 may substantially categorize the level of the main tank into three level states, which are: lower than the first level lower limit l1, lower than the first level upper limit l2 but higher than the first level lower limit l1, and higher than the first level upper limit l2. Therefore, the measurement in step S201 is to satisfy the subsequent measurement steps, and more precisely, the measurement in step S201 is to provide enough information to the processing controlling unit U1 to determine the liquid level, and is without other formal restriction.

Similar to step S201, in step S202, the second level gauges L3 and L4 measure the liquid level of the storage tank T2, and at least let the processing controlling unit U1 to be capable of determining whether the level in the storage tank T2 is lower than the second level lower limit l3, lower than the second level upper limit l4 but higher than the second level lower limit l3, or higher than the second level upper limit l4. Notably, step S202 is not necessarily carried out after step S201. The performing sequence of step S201 and S202 may be sequentially interchanged or in parallel, without any influence on the subsequent determination of the method for controlling level of the present invention. In addition, step S202 may also be performed between steps S203 and S204 or between steps S207 and S209.

In step S203, after receiving the liquid level information of the main tank T1, the processing controlling unit U1 determines whether the level of the main tank T1 is lower than the first level lower limit l1. When the processing controlling unit U1 determines that the level of the main tank T1 is lower than the first level lower limit l1 in step 203, it means that the electronic device to be cooled in the main tank T1 can not be fully soaked under the cooling liquid level and may be in risk of overheat. Next, in step S204, the processing controlling unit U1 acquires level information of the storage tank T2 and determines whether the liquid level of the storage tank T2 is lower than the second level lower limit l3. When the processing controlling unit U1 determines that the level of the storage tank T2 is not lower than the second level lower limit l3, it means that the cooling liquid in the storage tank T2 is sufficient to be provided for the use of the main tank T1, and therefore, the processing controlling unit U1 performs step S205. The processing controlling unit U1 opens the first valve V1 and turns on the pump P1 to input the liquid to the main tank T1 from the storage tank T2 through the first pipeline C1.

When the processing controlling unit U1 determines that the level of the main tank T1 is lower than the first level lower limit l1 and the level of the storage tank T2 is lower than the second level lower limit l3, the processing controlling unit U1 performs step S206: not taking further action, i.e. maintaining the original situation instead of opening the first valve V1 nor turning on the pump P1, thereby preventing the risk of the processing controlling unit U1 suddenly performing step S205, which may lead to the pump P1 sucking in air. Alternatively, when the processing controlling unit U1 determines that the level of the main tank T1 is lower than the first level lower limit l1 and the level of the storage tank T2 is lower than the second level lower limit l3, the processing controlling unit U1 may not only maintains the turn-off state of the first valve V1 and the pump P1, but also turns off the operation of the electronic devices to be cooled placed in the main tank T1, and outputs a first warning signal, thereby preventing the electronic devices to be cooled from being overheated and may inform the operators to replenish cooling liquid into the storage tank T2.

The above description about step S203 is to cover the situation that when the main tank T1 is in need of replenishing cooling liquid. However, if the level of the main tank T1 is not lower than the first level lower limit l1, the processing controlling unit U1 performs step S207 to determine whether the level of the main tank T1 is higher than the first level upper limit l2. If the level of the main tank T1 is not higher than the first level upper limit l2, it means that the level of the main tank T1 is within a safe range, and therefore, the processing controlling unit U1 may not take further action as shown in step S208.

But in step S207, when the level of the main tank T1 is too high, the processing controlling unit U1 may perform step S209, thereby determining whether the level of the storage tank T2 is higher than the second level upper limit l4, to determine whether the storage tank T2 can accommodate excessive liquid in the main tank T1. If the storage tank T2 has sufficient space inside, the processing controlling unit U1 may perform step S210. In other words, when the processing controlling unit U1 determines that the level of the main tank T1 is higher than the first level upper limit l2 and the level of the storage tank T2 is not higher than the second level upper limit l4, the processing controlling unit U1 opens the second valve V2 to input the liquid into the storage tank T2 from the main tank T1 through the second pipeline C2, and since there is a height difference between two connection sites of the second pipeline C2 with the main tank T1 and the storage tank T2, the process of transferring liquid in step S210 does not need operation from the pump P1. In step S209, when the processing controlling unit U1 determines that the level of the main tank T1 is higher than the first level upper limit l2 and the level of the storage tank T2 is higher than the second level upper limit l4, the processing controlling unit U1 may perform step S211: not taking further action, i.e. maintaining the original situation instead of opening the second valve V2, thereby preventing the risk of the processing controlling unit U1 suddenly performing step S210, which may lead to the level of the storage tank T2 being too high. Alternatively, When the processing controlling unit U1 determines that the level of the main tank T1 is higher than the first level upper limit l2 and the level of the storage tank T2 is higher than the second level upper limit l4, the processing controlling unit U1 may not only maintain the turn-off state of the second valve V2, but also outputs a second warning signal, thereby informing the operators to properly discharge cooling liquid in the storage tank T2.

Furthermore, after the processing controlling unit U1 determines that the level of the main tank T1 is within a safe range for a time interval, the processing controlling unit U1 can once again acquire the level of the main tank T1 from the first level gauges L1 and L2 and the level of the storage tank T2 from the second level gauges L3 and L4 to perform the described step S203 and the following determination or to take further actions.

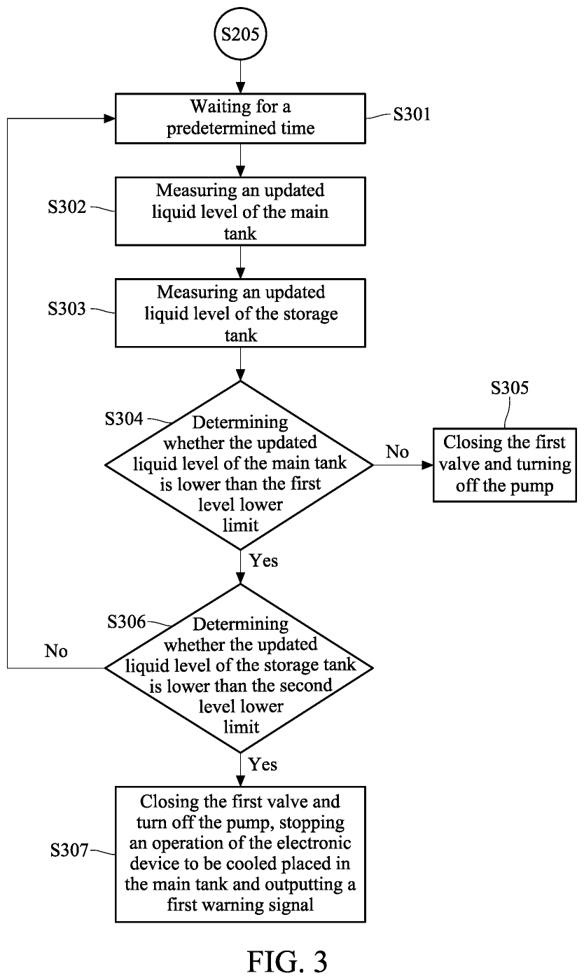

Please refer to FIG. 3 which is a flowchart illustrating a method for controlling liquid level of an immersion cooling system according to another embodiment of the present invention. The embodiment illustrated in FIG. 3 also comprises the main steps S201 to S211 illustrated in FIG. 2 with the same operation as the described embodiment, thus the description of the repetitive part may be omitted. In this embodiment, as the level of the main tank T1 is lower than the first level lower limit l1 and the level of the storage tank T2 is not lower than the second level lower limit l3, the first valve V1 is opened and the pump P1 is turned on in step S205. Next, in step S301, the processing controlling unit U1 may perform a confirmation procedure after opening the first valve V1 and turning on the pump P1 for a predetermined time. The processing controlling unit U1 performs steps S302 and S303, to control the first level gauges L1 and L2 to measure an updated liquid level of the main tank T1 and to control the second level gauges L3 and L4 to measure an updated liquid level of the storage tank T2, wherein steps S302 and S303 may be sequentially interchanged or in parallel, or step S303 may be performed between steps S304 and S306 described below.

In step S304 according to the embodiment, when the processing controlling unit U1 determines that the updated level of the main tank T1 is not lower than the first level lower limit l1, it means that the liquid which was input into the main tank T1 from the storage tank T2 is enough, hence the processing controlling unit U1 may close the first valve V1 and turn off the pump P1, which is step S305. However, when the processing controlling unit U1 determines that the updated level of the main tank T1 is still lower than the first level lower limit l1, it means that the liquid which was input into the main tank T1 from the storage tank T2 is not enough, hence the processing controlling unit U1 may further determine whether the updated level of the storage tank T2 is lower than the second level lower limit l3 in step S306. When the processing controlling unit U1 determines that the updated level of the main tank T1 is lower than the first level lower limit l1 and the updated level of the storage tank T2 is not lower than the second level lower limit l3, the processing controlling unit U1 waits for the predetermined time to perform step S301 again, and maintains the pump P1 to still be turned on and the first valve V1 to still be opened. But in step S306, as the processing controlling unit U1 determines that the updated level of the main tank T1 is lower than the first level lower limit l1 and the updated level of the storage tank T2 is lower than the second level lower limit l3, the processing controlling unit U1 closes the first valve V1, turns off the pump P1, switches off the electronic devices to be cooled in the main tank T1, and outputs the first warning signal, which means that the processing controlling unit U1 performs step S307.

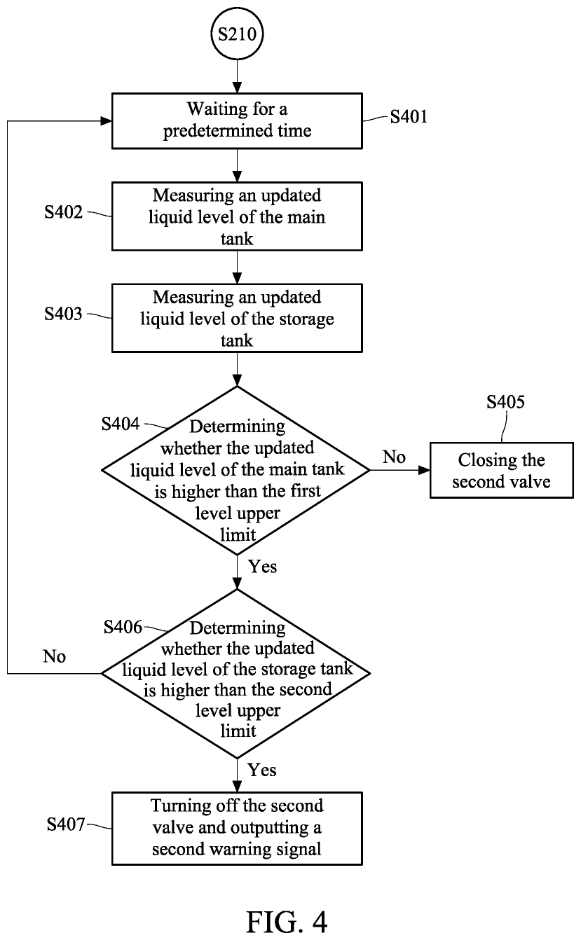

Please refer to FIG. 4 which is a flowchart illustrating a method for controlling liquid level of an immersion cooling system according to still another embodiment of the present invention. The embodiment illustrated in FIG. 4 also comprises the main steps S201 to S211 illustrated in FIG. 2 with the same operation as the described embodiment, thus the description of the repetitive part may be omitted. In this embodiment, as the level of the main tank T1 is higher than the first level upper limit l2 and the level of the storage tank T2 is not higher than the second level upper limit l4, the second valve V2 may be opened in step S210. Next, in step S401, the processing controlling unit U1 may perform a confirmation procedure after opening the second valve V2 for a predetermined time. Next, in steps S402 and S403, the processing controlling unit U1 may control the first level gauges L1 and L2 to measure an updated level of the main tank T1, and control the second level gauges L3 and L4 to measure an updated level of the storage tank T2, wherein steps S402 and S403 may be sequentially interchanged or in parallel, or step S403 may be performed between steps S404 and S406 described below.

In step S404 according to the embodiment, when the processing controlling unit U1 determines that the updated level of the main tank T1 is not higher than the first level upper limit l2, it means that the liquid which was input into the storage tank T2 from the main tank T1 is enough, hence the processing controlling unit U1 may close the second valve V2, which is step S405. However, when the processing controlling unit U1 determines that the updated level of the main tank T1 is still higher than the first level upper limit l2, it means that the liquid which was input into the storage tank T2 from the main tank T1 is not enough, hence the processing controlling unit U1 may further determine whether the updated level of the storage tank T2 is higher than the second level upper limit l4 in step S406. When the processing controlling unit U1 determines that the updated level of the main tank T1 is higher than the first level upper limit l2 and the updated level of the storage tank T2 is not higher than the second level lower limit l4, the processing controlling unit U1 waits for the predetermined time to perform step S401 again, and let the second valve V2 to still be opened. But in step S406, as the processing controlling unit U1 determines that the updated level of the main tank T1 is higher than the first level upper limit l2 and the updated level of the storage tank T2 is higher than the second level upper limit l4, the processing controlling unit U1 closes the second valve V2 and outputs the second warning signal, which is step S407.

The immersion cooling system and level control method thereof according to one or more embodiments described above may regulate the liquid level and provide buffering to the main tank T1 by the storage tank T2, to reduce requirement of man work. In addition, the part that mainly requires manual regulation of the liquid level comes from the first warning signal and the second warning signal, and the regulation to the liquid level of the storage tank T2 may further reduce the obstruction to the function of the electronic devices in the main tank T1.

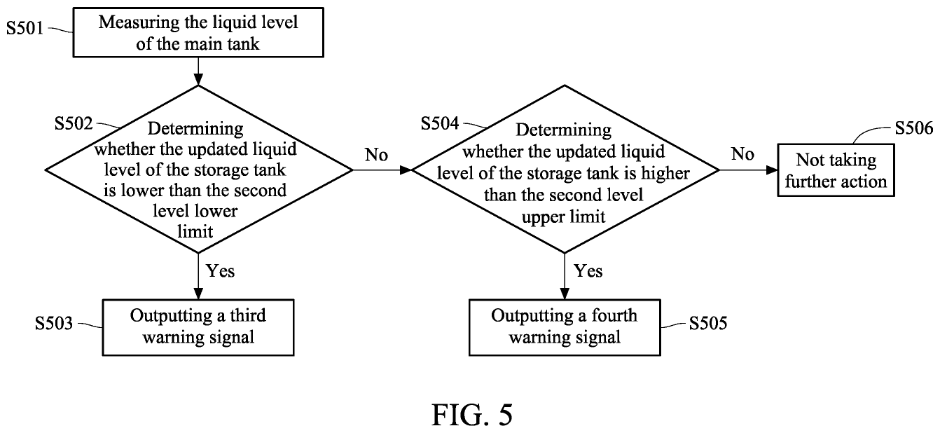

The further another embodiment according to the present invention provides a level control method with additionally monitoring the level of the storage tank T2. Please refer to FIG. 5, which is a flowchart illustrating a method for controlling liquid level of an immersion cooling system according to further another embodiment of the present invention. Step S501 is the same as step S201 for measuring the level of the main tank T1. Different from the described embodiments, when the processing controlling unit U1 determines that the level of the storage tank T2 is lower than the second level lower limit l3 in step S502, the processing controlling unit U1 may perform step S503 and output a third warning signal. When the processing controlling unit U1 determines that the level of the storage tank T2 is not lower than the second level lower limit l3, the processing controlling unit U1 may perform step S504 to determine whether the level of the storage tank T2 is higher than the second level upper limit l4. When the level of the storage tank T2 is not higher than the second level upper limit l4, it means that the level of the storage tank T2 is normal and there is no need of taking further action, which is step S506. When the processing controlling unit U1 determines that the level of the storage tank is higher than the second level upper limit l4, the processing controlling unit U1 outputs a fourth warning signal.

It should be noted that, the present embodiment also has steps S201 to S211 described above and further has steps S501 to S506. The advantageous effect of the present embodiment lies in that, no matter which of the first warning signal or the second warning signal mentioned above is delivered, the main tank T1 is already in an abnormal level condition; while when the third warning signal or the fourth warning signal is delivered in this embodiment, the main tank T1 may still be in a situation with normal level. In other words, the liquid control method according to the present embodiment may additionally measure and determine the level of the storage tank T2, to further effectively reduce the possible negative influence to the electronic devices in the main tank T1.

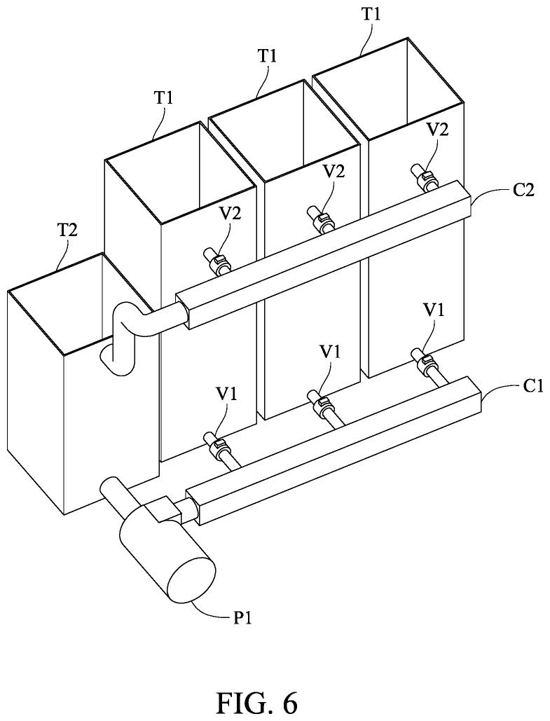

Please refer to FIG. 6 which is a structural schematic diagram illustrating an immersion cooling system according to another embodiment of the present invention. The present embodiment illustrated in FIG. 6 is intended to point out that, the storage tank T2 and the main tank T1 may not be in a one-on-one relationship. There are a number of main tanks T1 in this embodiment and the processing controlling unit U1 may follow the mechanism of the described embodiments to regulate the liquid when the level of any one of the main tanks T1 is determined to be not within the safety range. The processing controlling unit U1 may be further configured to output a warning signal when determining the level of the storage tank T2 is lower than the second level lower limit l3 or higher than the second level upper limit l4. The controlling structure of the plurality of main tanks T1 connected to the storage tank T2 through the pipelines C1 and C2 is highly efficient, and in combination with the level control method illustrated in FIG. 3 and FIG. 4, the processing controlling unit U1 may further re-measure the levels of the main tank T1 and the storage tank T2 after a predetermined time has passed after the warning signal is delivered. The reason is that, even there is no operator performing level regulation when the level of the storage tank T2 is too low or too high, the other main tanks T1 may also perform interchange of the liquid with the storage tank T2, to achieve a possible self-regulating system. In addition, the pump P1, the first valve V1 and the second valve V2 have the same function as described above and hence the description of the repetitive part will be omitted.

In view of the above description, an immersion cooling system and level control method thereof disclosed in the present invention provides a structure of the main tank in connection with the storage tank through pipelines, with the function of the level gauge, the pump and the processing controlling unit, to perform determination according to a measurement of the level of the main tank and the storage tank, and to further control the opening of the valve and turning on the pump. Therefore, liquid may be inputted into the storage tank from the main tank or liquid may be inputted into the main tank from the storage tank without encountering a situation that the level of the storage tank is too low to provide liquid into the main tank or that the level of the storage tank is too high to further accept liquid from the main tank. Accordingly, proper amount of cooling liquid inside the main tank may be ensured, so that the shutdown duration due to level variation in system may be reduced and the operation of cooling may be simplified. Furthermore, by the design of the connection site between the main tank and the second pipeline being higher than the connection site between the storage tank and the second pipeline, gravitational effect of height difference may be used to reduce energy loss required to perform reflow, which is helpful to efficiently maintain the operation of the immersion cooling system and to reduce the cost of man work and the disruption time.

According to an embodiment of the present invention, the immersion cooling system and the level control method thereof may be applied to a server, which may be used in artificial intelligence computing and edge computing, and may also be used as a 5G server, a cloud server or a server for internet of vehicles.

Although the present invention is disclosed in the foregoing embodiments, it is not intended to limit the present invention. Change and modifications made without departing from the spirit and scope of the present invention belong to the scope of the present invention. For the protection scope defined by the present invention, please refer to the attached claims.

What is claimed is:

1. A method for controlling liquid level of an immersion cooling system, comprising:
providing a main tank and a storage tank, wherein the main tank has a first level lower limit and a first level upper limit, the storage tank has a second level lower limit and a second level upper limit, the main tank and the storage tank are connected to each other through a first pipeline and a second pipeline, the first pipeline is provided with a first valve and a pump, the second pipeline is provided with a second valve, and a connection site between the second pipeline and the main tank is higher than a connection site between the second pipeline and the storage tank and is lower than or equal to the first level upper limit;
measuring a level of the main tank with a set of first level gauges;
measuring a level of the storage tank with a set of second level gauges; and
by a processing controlling unit, performing:
when it is determined that the level of the main tank is lower than the first level lower limit and the level of the storage tank is higher than the second level lower limit, opening the first valve and turning on the pump to input liquid into the main tank from the storage tank through the first pipeline; and
when it is determined that the level of the main tank is higher than the first level upper limit and the level of the storage tank is not higher than the second level upper limit, opening the second valve to input liquid into the storage tank from the main tank through the second pipeline.

2. The method for controlling level of the immersion cooling system of claim 1, further comprising, by the processing controlling unit, performing:
when it is determined that the level of the main tank is lower than the first level lower limit and the level of the storage tank is lower than the second level lower limit, stopping an operation of an electronic device to be cooled placed in the main tank and outputting a first warning signal; and
when it is determined that the level of the main tank is higher than the first level upper limit and the level of the storage tank is higher than the second level upper limit, outputting a second warning signal.

3. The method for controlling level of the immersion cooling system of claim 1, further comprising, by the processing controlling unit performing a confirmation procedure after opening the first valve, turning on the pump and waiting for a predetermined time, wherein the confirmation procedure comprises:
controlling the set of first level gauges to measure an updated level of the main tank;
controlling the set of second level gauges to measure an updated level of the storage tank;
when it is determined that the updated level of the main tank is not lower than the first level lower limit, closing the first valve and turning off the pump;
when it is determined that the updated level of the main tank is lower than the first level lower limit and the updated level of the storage tank is lower than the second level lower limit, closing the first valve, turning off the pump, stopping an operation of an electronic device to be cooled placed in the main tank and outputting a first warning signal; and
when it is determined that the updated level of the main tank is lower than the first level lower limit and the updated level of the storage tank is not lower than the second level lower limit, waiting for the predetermined time to perform the confirmation procedure again.

4. The method for controlling level of the immersion cooling system of claim 1, further comprising, by the processing controlling unit, performing a confirmation procedure after opening the second valve and waiting for a predetermined time, wherein the confirmation procedure comprises:
controlling the set of first level gauges to measure an updated level of the main tank;
controlling the set of second level gauges to measure an updated level of the storage tank;
when it is determined that the updated level of the main tank is not higher than the first level lower limit, closing the second valve;
when it is determined that the updated level of the main tank is higher than the first level upper limit and the updated level of the storage tank is higher than the second level upper limit, closing the second valve and outputting a second warning signal; and
when it is determined that the updated level of the main tank is higher than the first level upper limit and the updated level of the storage tank is not higher than the second level upper limit, waiting for the predetermined time to perform the confirmation procedure again.

5. The method for controlling level of the immersion cooling system of claim 1, further comprising, by the processing controlling unit, performing:
when it is determined that the level of the storage tank is lower than the second level lower limit, outputting a third warning signal; and
when it is determined that the level of the storage tank is higher than the second level upper limit, outputting a fourth warning signal.

6. An immersion cooling system, comprising:
a main tank having a first level lower limit and a first level upper limit, and configured to accommodate an electronic device to be cooled;
a storage tank having a second level lower limit and a second level upper limit, and connecting to the main tank through a first pipeline and a second pipeline, wherein the first pipeline is provided with a first valve and a pump, the second pipeline is provided with a second valve, and a connection site between the second pipeline and the main tank is higher than a connection site between the second pipeline and the storage tank and is lower than or equal to the first level upper limit;
a set of first level gauges disposed in the main tank, configured to measure a level of the main tank;
a set of second level gauges disposed in the storage tank, configured to measure a level of the storage tank; and
a processing controlling unit connected to the first valve, the second valve, the pump, the set of first level gauges and the set of second level gauges, and configured to perform:
when it is determined that the level of the main tank is lower than the first level lower limit and the level of the storage tank is higher than the second level lower limit, opening the first valve and turning on the pump to input liquid into the main tank from the storage tank through the first pipeline; and
when it is determined that the level of the main tank is higher than the first level upper limit and the level of the storage tank is not higher than the second level upper limit, opening the second valve to input liquid into the storage tank from the main tank through the second pipeline.

7. The immersion cooling system of claim 6, wherein the set of first level gauges comprises two gauges disposed at the first level upper limit and the first level lower limit respectively, and the set of second level gauges comprises two gauges disposed at the second level upper limit and the second level lower limit respectively.

8. The immersion cooling system of claim 6, wherein the second level lower limit is higher than the connection site between the storage tank and the first pipeline.

9. The immersion cooling system of claim 6, wherein the first level upper limit is lower than a condenser disposed in the main tank.

10. The immersion cooling system of claim 6, wherein an amount of the main tank is more than 1, and the processing controlling unit is further configured to output a warning signal when it is determined that the level of the storage tank is lower than the second level lower limit or the level of the storage tank is higher than the second level upper limit.
